(19) United States
(12) Patent Application Publication
(10) Pub. No.: US 2005/0161158 A1
(43) Pub. Date: Jul. 28, 2005

(54) Exhaust conditioning system for semiconductor reactor

(76) Inventor: John C. Schumacher, Carlsbad, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/022,568

(22) Filed: Dec. 23, 2004

Related U.S. Application Data
(60) Provisional application No. 60/532,186, filed on Dec. 23, 2003.

(51) Int. Cl. H01L 21/306

(52) U.S. Cl. 156/345.29

(57) ABSTRACT

The invention relates generally to an exhaust system and, in particular, to an exhaust conditioning system including overpressure and/or backflow protection and a combined trap/muffler for semiconductor etch and deposition processes. Advantages include automatic continuous operation, substantially zero lost wafers from unscheduled vacuum pump shut down, reduced particulate defects and improved yield.

### RELATED APPLICATIONS

This application claims the benefit of U.S. Provisional Patent Application Ser. No. 60/532,186, filed Dec. 23, 2003, entitled EXHAUST SYSTEM FOR SEMICONDUCTOR REACTOR, the entirety of which is hereby incorporated by reference herein.

### BACKGROUND OF THE INVENTION

1. Field of the Invention

The invention relates generally to an exhaust system and, in particular, to an exhaust conditioning system including overpressure and/or backflow protection and a combined trap/muffler for semiconductor etch and deposition processes.

2. Description of the Related Art

Many semiconductor device fabrication processes are subject to interruption, instability and loss of process control as a result of solid and liquid deposition in the exhaust system through which process effluent is vented to the atmosphere. Most such processes operate at sub-atmospheric pressure in order to promote deposited or etched film uniformity and run to run repeatability in the process chamber, so that this exhaust system includes a vacuum pump.

Heating the entire exhaust system to the order of 90° C. to 140° C. can solve much of the vacuum exhaust system clogging problem. However, disadvantageously, this solution is prohibitively expensive from both a capital and operating cost perspective.

A second complicating component of the problem is the fact that the process effluents involved must be treated with air pollution control devices prior to their discharge from a manufacturing facility into the environment. This has led some who have experienced the problem to seek to solve it by placing a Point Of Use (“POU”) abatement device in the exhaust system at the point where the clogging occurs. For processes that utilize moisture sensitive reactants such as conductor deposition and etch, this approach not only is totally ineffective, it unnecessarily adds greatly to the monetary cost in and resources needed to solve the problem.

Conventional technologies have sought to alleviate this vacuum exhaust system clogging. But these technologies however solve only part of the problem, in that the deposition responsible for the interruption, instability and loss of process control is not completely eliminated as a practical consideration by their use.

### SUMMARY OF THE INVENTION

Embodiments of the invention overcome some or all of the shortcomings of conventional technologies regarding treatment of vacuum exhaust system clogging in conductor deposition and etch processes. Advantages include automatic continuous operation, substantially zero lost wafers from unscheduled vacuum pump shut down, reduced particulate defects and improved yield.

In accordance with one embodiment, an exhaust system for a semiconductor processing chamber is provided. The exhaust system generally comprises a diverter valve, a pressure sensor, an exhaust run line, an exhaust bypass line and a filter. The diverter valve is downstream of a vacuum pump that is downstream of the semiconductor processing chamber. The pressure sensor is upstream of the diverter valve for monitoring pump back pressure. The exhaust run line is downstream of the diverter valve through which exhaust from the semiconductor processing chamber is fed to a facility exhaust line. The exhaust bypass line is downstream of the diverter valve and arranged in a parallel configuration with the exhaust run line. The filter is at the exhaust run line to capture at least a portion of particulates and/or condensable vapor of the exhaust as it passes through the filter. Advantageously, the diverter valve is actuated to direct the exhaust through the exhaust bypass line if the back pressure as measured by the pressure sensor increases by a predetermined pressure differential (ΔP) to allow substantially continuous operation of the semiconductor processing chamber.

In accordance with another embodiment, a method of directing exhaust from a semiconductor processing chamber is provided. The method comprises flowing the exhaust through a diverter valve downstream of a pump that provides sub-atmospheric pressure to the semiconductor processing chamber. The exhaust flows through a filter downstream of the valve to remove at least a portion of particulates and/or condensable vapor of the exhaust. The exhaust that passes through the filter is fed to a facility exhaust line downstream of the filter. The back pressure intermediate the pump and the valve is monitored. The valve is operated to divert the exhaust to an exhaust bypass line if the back pressure increases by a predetermined pressure differential (ΔP) to allow substantially continuous operation of the semiconductor processing chamber.

In accordance with yet another embodiment, an exhaust system for a semiconductor processing chamber is provided. The exhaust system generally comprises an exhaust line, a trap and an injector. The exhaust line is downstream of a vacuum pump that is downstream of the semiconductor processing chamber. The trap is in the exhaust line and generally comprises a chamber filled with filter material, wherein the trap serves as a muffler of exhaust noise and no other muffler is provided in the vacuum pump and between the vacuum pump and the trap. The injector is downstream of the trap that feeds into a facility exhaust. The injector is configured to prevent reactive vapor backstreaming and backstreaming induced deposition.

For purposes of summarizing the invention, certain aspects, advantages and novel features of the invention have been described herein above. Of course, it is to be understood that not necessarily all such advantages may be achieved in accordance with any particular embodiment of the invention. Thus, the invention may be embodied or carried out in a manner that achieves or optimizes one advantage or group of advantages as taught or suggested herein without necessarily achieving other advantages as may be taught or suggested herein.

All of these embodiments are intended to be within the scope of the invention herein disclosed. These and other embodiments of the invention will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

Having thus summarized the general nature of the invention and some of its features and advantages, certain preferred embodiments and modifications thereof will become apparent to those skilled in the art from the detailed description herein having reference to the figures that follow, of which:

FIG. 1 is a graph showing experimental data that depicts an undesirable rise in back pressure in an exhaust line of a semiconductor fabrication system.

FIG. 2 is a simplified schematic view of an exhaust conditioning system connected to a vacuum pump downstream of a semiconductor reactor having features and advantages in accordance with one embodiment of the invention.

FIG. 3 is a simplified side view of an automated exhaust conditioning system for a semiconductor reactor having features and advantages in accordance with one embodiment of the invention.

FIG. 4 is a simplified front view of the exhaust conditioning system of FIG. 3 having features and advantages in accordance with one embodiment of the invention.

FIG. 5 is a simplified top view of the exhaust conditioning system of FIG. 3 having features and advantages in accordance with one embodiment of the invention.

FIG. 6 is a graph showing experimental data that depicts improved semiconductor fabrication system performance when utilizing an exhaust conditioning system in accordance with embodiments of the invention.

FIG. 7 is a simplified sectional view of an injector device of the exhaust conditioning system of FIGS. 2-5 having features and advantages in accordance with one embodiment of the invention.

FIG. 8 is a graph illustrating the variation of Reynolds Number with flow rate for flow of the non-reactive gas through an annular space of the injector device of FIG. 7.

FIG. 9 is a simplified top view of a combined trap and muffler of the exhaust conditioning system of FIGS. 2-5 having features and advantages in accordance with one embodiment of the invention.

FIG. 10 is a simplified sectional view along line 10-10 of FIG. 9.

FIG. 11 is a simplified front view of an exhaust outlet tube of the combined trap and muffler of FIG. 9 having features and advantages in accordance with one embodiment of the invention.

FIG. 12 is a simplified top view of a combined trap and muffler of the exhaust conditioning system of FIGS. 2-5 having features and advantages in accordance with another embodiment of the invention.

FIG. 13 is a simplified sectional view along line 13-13 of FIG. 12.

FIG. 14 is a simplified schematic view of an automated exhaust conditioning system including a second exhaust run line and connected to a vacuum pump downstream of a semiconductor reactor having features and advantages in accordance with another embodiment of the invention.

FIG. 15 is a simplified front view of an exhaust conditioning system for a semiconductor reactor including a second exhaust run line having features and advantages in accordance with another embodiment of the invention.

FIG. 16 is a simplified perspective view of a dual unit automated exhaust conditioning system for a semiconductor reactor having features and advantages in accordance with yet another embodiment of the invention.

### DETAILED DESCRIPTION OF THE PREFERRED EMBODIMENT

The preferred embodiments of the invention described herein relate generally to an exhaust system and, in particular, to an exhaust conditioning system including backflow protection and a combined trap/muffler for semiconductor etch and deposition processes.

While the description sets forth various embodiment specific details, it will be appreciated that the description is illustrative only and should not be construed in any way as limiting the invention. Furthermore, various applications of the invention, and modifications thereto, which may occur to those who are skilled in the art, are also encompassed by the general concepts described herein.

Vacuum Exhaust Clogging Problem

In fabricating a semiconductor device, conductors as well as insulators are deposited on and etched from a silicon substrate. During these deposition and etch process steps, deposits form on the walls of the chamber in which the process is being carried out. Such deposits are derived from a number of sources including reactant impurities, reaction products and byproducts, as well as moisture adsorption or backstreaming. Particles can settle throughout the reaction chamber including on the wafer(s) being processed. Deposits build up between chamber cleaning operations, which are scheduled so as to control particulate additions to the wafer, per wafer pass to within specifications.

Disadvantageously, deposition is not limited to the process chamber, but occurs in the vacuum exhaust system as well. However, deposition downstream of the process chamber typically proceeds on a different timeline from that in the chamber. It comprises of deposition of solid reaction products of the etching process, for example, AlCl₃, and the reaction products created by moisture leaking or “backstreaming” into the vacuum exhaust system from downstream. B₂O₃ created by excess BCl₃ reactant and SiO₂ by poly etching product SiHBr₃ reactions with moisture respectively, are examples of the latter.

As discussed further below, it has been suggested that clogging of a conventional vacuum exhaust line downstream of the pump causes particulate “showers” that result in yield degradation in metal and poly etch tool process chambers. Such particulate showers can comprise of large quantities of material suddenly breaking free from that deposited on process chamber walls between chamber clean operations. The showers occur when the vacuum pump sees high back pressure as a result of deposition in the vacuum exhaust line, downstream of the pump, in the later stages of the interval between scheduled chamber clean operations. Furthermore, vacuum exhaust clogging has been suggested to explain the fact that conductor etch processes represent some of the top contributors to yield degradation based on particles per square meter added per wafer pass, as noted further below.

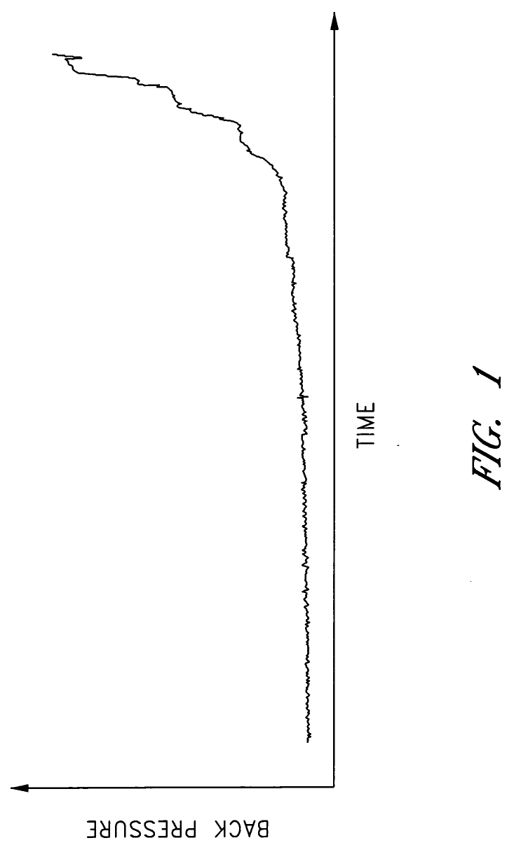

As shown in FIG. 1, a sudden onset of significant back pressure (seen by the vacuum pump) has also been found experimentally. It should be noted that the pressure drop can increase from no apparent problem to an overpressure alarm condition (e.g. about 3 psi or greater) in a single 24 hour period. If undetected, this would undesirably result in an unscheduled production shut down, perhaps during a processing cycle. Disadvantageously, wafers could be adversely affected and damaged.

Particulate Related Yield Degradation Mechanisms

In addition to producing unending maintenance headaches, conventional conductor etch processes are major contributors to yield degradation. This conclusion is based on the large number of particles added by conductor etch per wafer pass, and the high number of conductor etch passes during processing.

Aluminum, tungsten and poly etch have been identified as among the top on the yield degradation contributor process list. It has also been noted that metal and poly etch represent two of the top five contributors to yield degradation. This effect has also been quantified to point out that metal and poly etch can provide a minimum of 17.67% of the total # particles/area Budget for MPU processing and 13.25% for DRAM processing respectively.

Evidence has suggested that particulate “showers” in the chamber cause low yield in conductor etch processes. It is contemplated that build up of back pressure caused by clogging over time of the vacuum exhaust line (also referred to as the 1.5 inch vacuum exhaust line), downstream of the mechanical pump, causes the “showers” of particles in conductor etch tool process chambers that result in yield loss.

Airborne particulate material can be created in conductor etch process chambers by homogeneous nucleation of solid AlCl₃, B or WOₓF_{y} in the vapor phase via the following chemical reactions.

Aluminum Etch:
3Cl₂+3Al+3BCl₃+3H₂O⇄3AlCl₃(↓)+B(↓)+B₂O₃(↓)+6 HCl

Poly Etch:
Si+3HBr+2H₂O⇄SiHBr₃+H₂+2H₂O⇄SiO₂(↓)+3HBr

Tungsten Etch:
3W+2CF₄+6H₂O⇄WOF₄(↓)+CₓF_{y}H_{z}+WO₂F₂(↓)+WO₃(↓)

Solid etch reaction products, designated by (↓) in the foregoing reaction equation summary first form a critical nucleus and then enter a growth phase prior to “settling out” as particulate matter as they travel through the vacuum exhaust system. A propensity for nucleation leads to a long mean free path, while a propensity for growth leads to little nucleation.

In either case, clogging upstream of the mechanical vacuum pump where pressure is low, molecular collisions infrequent and opportunity for growth by agglomeration rare, deposition is minimal.

Despite the minimal extent of deposits upstream of the mechanical pump, they build up over time and require periodic chamber wet clean operations. These are scheduled so as to control particulate additions to the wafer per process pass within limits.

In addition, upstream wall deposits are not static and passivated. Particles break free from them as a result of turbulent convection, and are added to those already in flight by virtue of homogeneous nucleation. High pumping speeds are required to remove this particulate matter from the vicinity of the wafer.

Downstream of the mechanical pump pressure is high, and collisions with walls and other particles are frequent. Agglomeration as a result is prevalent and deposition rapid and severe.

Here, solid etch process reaction product particles of AlCl₃, B and WOₓF_{y}, condense on cold exhaust system walls. Moisture sensitive gas phase etching reactant BCl₃ and reaction product SiHBᵣ₃ also form solid B₂O₃ or SiO₂ wall deposits when air leaks, or “backstreams” into the vacuum exhaust system from the facility scrubbed exhaust or a POU scrubber.

As the vacuum pump sees higher backpressure due to such downstream deposition, it loses efficiency and pumping speed. This crimps its ability to remove in-flight particulate matter from the vicinity of the wafer being processed.

Eliminating downstream deposition on the other hand, as embodiments of the invention desirably provide, raises pumping speed and efficiency, thereby reducing the particles added per wafer. Embodiments of the invention, advantageously, monitor and control build up of mechanical vacuum pump back pressure and solid deposits, thereby providing real time metal etch process control. In conventional systems, only lagging indicator (particle count) monitoring is typical. Embodiments of the invention, desirably, substantially eliminate or mitigate undesirable vacuum exhaust clogging and dramatically reduce particles added per wafer pass thereby improving yield.

System Overview

Embodiments of the invention provide an exhaust conditioning system to provide a large number of beneficial effects in integrated circuit manufacturing. The system generally comprises a backstreaming prevention gas injector device in series with a combined trap and Muffler, and in parallel with a backpressure activated bypass exhaust line.

It is important to pay attention to vacuum pump backpressure because this controls the efficiency of removal of potential defects from the area in which the silicon wafer on which the integrated circuits are being manufactured, is processed. Maintaining low backpressure will result in low defects and increase the yield of good integrated circuit chips (or “die”). This can be accomplished by installing a pressure sensor in the system to monitor backpressure and then on a predetermined rise in pressure to signal a diverter valve to divert flow from the muffler/trap/gas injector path to a bypass path while activating a horn or the like to alert technicians to the need to service and/or replace the filter element in the combined trap/muffler. Advantageously, this will provide real time process control which will lead to significant increases in manufacturing yield of good integrated circuits and other benefits, as described below.

Automatic Continuous Operation

In some embodiments, the combined trap/muffler replaces the muffler on the conventional vacuum pump which if not replaced acts as a somewhat inefficient trap but requires the pump and the process to be periodically shut down for cleaning. Both the muffler and the trap/muffler condense and collect solid forming materials contained in the exhaust coming directly from the reaction chamber.

The gas injector desirably prevents moisture backstreaming and resultant clog formation from reaction with moisture sensitive materials in the process exhaust.

The replacement of the conventional pump muffler by the combined trap/muffler of embodiments of the invention desirably allows easy access for clean out. Pump back pressure is sensed continuously, and process exhaust automatically is changed from being fed to the combined muffler/trap to a bypass line if pressure builds, to allow off-line maintenance that is completely transparent to manufacturing. One objective of the invention, zero process downtime, results.

Zero Lost Wafers from Unscheduled Vacuum Pump Shut Down

In today's semiconductor industry, a single 8″ wafer when finished processing will typically contain between $10,000 and $100,000 worth of integrated circuits, depending on their exact design and function. Typically each conductor etch tool will experience one unscheduled shut down every two years due to an overpressure event, or 0.5 event per year, at a cost of $5,000 to $50,000. A typical integrated circuit fabricator will have approximately 20 conductor etch tools. Preventing unscheduled process interruption due to overpressure will therefore save a typical integrated circuit fabricator from $100,000 to $1,000,000 annually.

Embodiments of the invention provide an on-board backpressure monitor that initiates automatic switching of the exhaust from the trap to bypass preventing overpressure pump shut down.

Reduced Particulate Defects

As also discussed above, particulate material can be created in conductor etch process chambers by homogeneous nucleation of solid AlCl₃ or WCl₆ in the vapor phase. Despite hot walls and locally low pressure, minimal deposits build up over time via heterogeneous nucleation of the same compounds on chamber and exhaust system walls. These require periodic chamber wet clean operations, which are scheduled so as to control particulate additions to the wafer within specifications.

Wall deposits are not static and passivated however. Particles break free from them as a result of turbulent convection, and are added to those already in flight by virtue of homogeneous nucleation. High pumping speeds are required to remove this particulate matter from the vicinity of the wafer.

Downstream of the vacuum pump, exhaust wall deposition proceeds via a different mechanism from that seen upstream. Here, static pressure is only slightly below atmospheric and walls are generally not heated to high temperature. Deposit build up is severe and rapid.

Solid etch process reaction products AlCl₃ and WCl₆ condense on cold exhaust system walls. Moisture sensitive gas phase etching reactant BCl₃ and reaction product SiHBr₃ also form solid B₂O3 or SiO₂ wall deposits when air leaks, or “backstreams” into the vacuum exhaust system from the facility scrubbed exhaust.

As the vacuum pump sees ever higher back pressure as a result of such downstream deposition, it loses efficiency and pumping speed which crimps its ability to remove in-flight particulate matter from the vicinity of the wafer being processed. Eliminating downstream deposition should therefore improve pumping efficiency and thereby reduce the particles added to each wafer, as provided by the exhaust conditioning system of embodiments of the invention.

Improved Yield

A processed 8″ wafer as stated previously is generally worth about $10,000 but in certain instances its value can go as high as $100,000. It will have approximately 1350 die per wafer. Die are therefore worth about $7.50 but can be worth as much as $75.00.

Metal etch tools equipped with an exhaust conditioning system in accordance with embodiments of the invention have shown a yield of 2.5 to 3 more die than average. If a die is worth on average $10.25 for a company using the exhaust conditioning system in accordance with embodiments of the invention, this yield increase is worth more than $1.5 million per year for a company that processes 60,000 wafers annually.

Exhaust Conditioning System

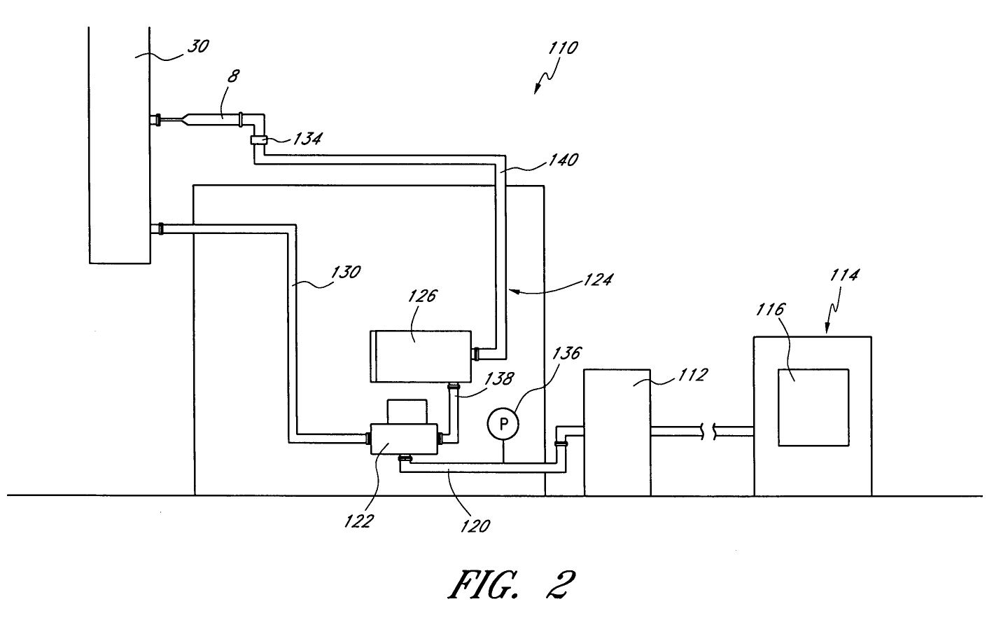

FIGS. 2-5 show different views of some embodiments of an exhaust or effluent conditioning or treatment system 110 for a semiconductor reactor. FIG. 2 also shows a mechanical vacuum pump 112 downstream of the system 110 and in fluid communication with a downstream semiconductor reactor or fabrication device 114.

The semiconductor reactor 114 comprises a semiconductor processing chamber 116 in which wafers are loaded and processed to facilitate in the fabrication of integrated circuit chips or dies. More particularly, the semiconductor reactor 114 comprises a plasma conductor or metal etch tool device for processing semiconductor wafers in the semiconductor process chamber 116.

The mechanical vacuum pump 112 connects to an upstream process tool “turbo-pump”. The pump 112 facilitates in pumping the semiconductor process chamber exhaust or effluent to a facility exhaust line and creates a vacuum, partial vacuum or sub-atmospheric pressure in the semiconductor process chamber 116.

The exhaust conditioning system 110 generally comprises an inlet line, pipe or tube 120, a diverter or bypass valve 122, an exhaust run line, pipe or tube 124, a combined muffler and particulate trap 126, a gas diode or duct injector device 8 and a bypass exhaust line, pipe or tube 130. The system 110 can comprise a suitable frame 132 or the like to house and/or support the various system components. A pressure gauge, sensor or transducer 136 is provided to measure and monitor the back pressure downstream of the pump 112 (or at or proximate to the pump exit).

As discussed further below, the injector device 8 and the bypass exhaust line feed into an outlet, facility or main exhaust line. One or more check valves 134 or the like may be utilized, as needed or desired.

The inlet exhaust line 120 connects to the outlet of the vacuum pump 112 and is downstream of the vacuum pump 112. The inlet line 120 is also connected to the inlet of the diverter valve 122 which is downstream of the inlet line 120.

The exhaust run line 124 comprises is downstream of the diverter valve 122 and comprises a first exhaust run line 138 and a second exhaust run line 140. The first exhaust run line 138 is connected to one of the outlets of the diverter valve 122 and to the inlet of the combined trap and muffler 126.

The second exhaust run line 140 is downstream of the combined trap and muffler 126. The second exhaust run line 140 is connected to the outlet of the combined trap and muffler 126 and to the inlet of the injector device 8.

The exhaust bypass line 130 is downstream of the diverter valve 122 and is arranged in parallel with the exhaust run line 124 and the combined trap and muffler 126. The exhaust bypass line 130 is connected to one of the outlets of the diverter valve 122 and feeds into an outlet, facility or main exhaust line, as discussed further below.

The diverter or bypass valve 122 is used to switch flow paths between the exhaust run line 124 and the exhaust bypass line 120 based on back pressure monitoring and advantageously facilitates operation of the semiconductor reactor 114 without process downtime, as discussed further below. The diverter valve 122 comprises a two-way valve or the like and may be manually or electronically controlled. Two or more one-way valves may also be efficaciously utilized to divert the exhaust flow, as needed or desired.

In one embodiment, the diverter valve 122 comprises one or more mechanical valves to control flow between the exhaust run line 124 and the exhaust bypass line 120. These mechanical valve(s) do not require electronic control and this adds to the simplicity, compactness and cost-effectiveness.

In another embodiment, the diverter valve 122 comprises a pneumatic or pneumatically actuated valve to control flow between the exhaust run line 124 and the exhaust bypass line 120. The pneumatic diverter valve is desirably electronically controlled to facilitate remote monitoring and automatic control based on back pressure measurements.

In one embodiment, the pneumatic diverter valve 122 is operated using compressed air at a pressure of about 80 psig. In modified embodiments, other suitable gas pressures may be efficaciously utilized, as needed or desired.

The combined solids trap and muffler 126 is positioned at the exhaust run line 124 or intermediate the first exhaust run line 138 and the second exhaust run line 140. The combined trap and muffler 126 is downstream of the first exhaust run line 138 and is arranged in series with the injector device 8. As discussed further below, the combined trap and muffler 126 comprises one or more filters that are used to trap exhaust particulates and/or condensable vapor and are serviced or replaced when the back pressure rises by a predetermined value or reaches a predetermined threshold value. Optionally, a second combined trap and muffler may be provided at the exhaust bypass line 130.

As described in further detail below, the combined solids trap and muffler 126 is specially designed in accordance with embodiments of the invention to perform the dual roles of removing particulates and/or condensable vapor from the process exhaust and muffling pump associated noise or sound. Advantageously, no muffler is needed within the vacuum pump 112 since otherwise this pump muffler would clog with particulates and could disrupt operation for maintenance purposes. Moreover, and disadvantageously, this conventional pump muffler is not easily accessible and is difficult to reach and maintain.

The gas injector device 8 is downstream of and arranged in series with the combined trap and muffler 126. As discussed further below, the injector device 8 feeds into an outlet, facility or main exhaust line.

As described in further detail below, the injector device 8 that allows exhaust gases to flow downstream while desirably preventing moisture (H₂O) and oxygen (O₂) “backstreaming” from the scrubbed exhaust towards the pump. Such backstreaming of moisture and O₂ causes exhaust lines to clog, which would undesirably inhibit flow downstream and raise back pressure on the vacuum pump exit. The injector device 8 utilizes a laminar flow blanket of an inert gas (in one embodiment, nitrogen (N₂)) to substantially eliminate undesirable backstreaming of O₂ and H₂O. Optionally, a second injector device may be provided at the exhaust bypass line 130.

In one embodiment, the injector device 8 and the exhaust bypass line 130 are mounted or connected to an outlet exhaust line, pipe, duct or tubing 30 (of the exhaust conditioning system 110) that in turn is connected to a facility “drop” or downwardly extending duct from a facility or main scrubbed exhaust duct system. In another embodiment, the outlet exhaust line 30 may comprise the “drop” itself to which the injector device 8 and the exhaust bypass line 130 are mounted or connected to. In yet another embodiment, the injector device 8 and the exhaust bypass line 130 are mounted or connected directly to the facility scrubbed exhaust. Optionally, the injector device 8 and the exhaust bypass line 130 may be connected to or feed into other devices such as an exhaust stack, scrubber or other gas processing apparatus.

A blast gate 142 or the like is used to control the downstream velocity in the “drop” duct to a predetermined value, in one embodiment, about 15 feet/sec (FPS). A fan on the facility scrubber (typically supplying a flow rate of about 50,000 to 100,000 ft³/min (CFM)) pulls room air through the scrubbed exhaust system at a velocity around 15 feet per second. This air enters the scrubbed exhaust system through such entry points as the blast gate 142 which when set at 15 FPS consumes about 177 CFM of the fan's capacity. Other entry points may include wet benches, gas cylinder storage cabinets and Point of Use air pollution control scrubbers. In one embodiment, an End of Pipe (“EOP”) technology is applied on the scrubbed exhaust to provide the required or desired air pollution control and abatement.

In one embodiment, the pressure gauge on the mechanical vacuum pump 112 itself is used to measure and monitor pressure or back pressure proximate the pump exit and determine when to service or replace the filter media of the combined trap and muffler 126. This embodiment in combination with the mechanical (not pneumatic) diverter valve embodiment, provide enhanced simplicity. The simple exhaust conditioning system 110 in accordance with this embodiment, can operate substantially without electrical power and, in one embodiment, has a weight of about 125 lbs, a compact frame (or substantially overall) size of about 20 inches (width)×30 inches (depth or length)×50 inches (height), and utilizes utility nitrogen (about 10 psig pressure) at a flow rate of about 1 CFM as the barrier gas for the injector device 8.

In another embodiment, the pressure measuring and sensing device 136 comprises a pressure sensor or transducer. The pressure sensor or transducer 136, in one embodiment, is located or positioned at the inlet line 120 substantially mid-way between the vacuum pump 112 and the diverter valve 122.

In one embodiment, the pressure sensor or transducer 136 comprises a stainless steel unit that has a range of about 0 to 5 psi with a 4 to 20 milliamp output and good linearity and a digital display. For example, an Ashcroft A2SBM0242D25#G, among others.

The exhaust conditioning system 110 in accordance with some embodiments of the invention comprises an electronics package or system that supplies power to operate various electronically controlled system components to operate and control them. In one embodiment, the electronics package or system provides suitable power to actuate or operate and control the pneumatic diverter valve 122, the pressure sensor or transducer 136 including the display and to actuate alarms, for example, lights, buzzer, horn to alert technicians when the back pressure has increased by a predetermined pressure difference or differential (ΔP). In one embodiment, two plug and play 110 volt AC and 5 amp electrical connections are provided.

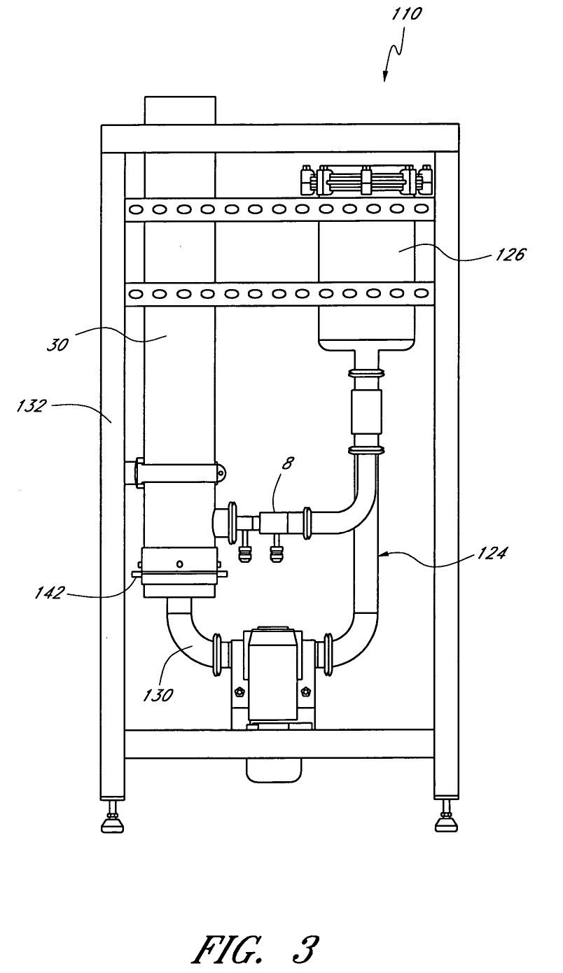

The automated and electronically supported exhaust conditioning system 110 (shown for example in FIGS. 3-5), in one embodiment, has a weight of about 225 lbs, a compact frame (or substantially overall) size of about 20 inches (width)×30 inches (depth or length)×50 inches (height), utilizes utility nitrogen (about 10 psig pressure) at a flow rate of about 1 CFM as the barrier gas for the injector device 8, utilizes compressed air at a pressure of about 80 psig to operate the pneumatically actuated diverter valve 122, and utilizes 110 volt AC and 5 amp electrical power connections.

In one embodiment, the exhaust conditioning system 110 is interfaced with a controller or control system or the like using suitable connection ports such as one or more RS 232 ports to allow remote monitoring and control. The controller facilitates automatic system control and operation of system components (e.g., diverter valve 122, pressure sensor 136 and alarms) and can comprise a computer, microprocessor and other suitable hardware and software, as needed or desired.

In one embodiment, at least a portion of the exhaust run line 124 and/or the inlet line 120 are insulated and/or heated to provide temperature control. The conductor etch process typically runs at about a few hundred degrees Centigrade. When the gases from this process exit the mechanical vacuum pump they are at around 80° C. At this temperature no deposition occurs between the mechanical pump and the diverter valve. The system, in one embodiment, has insulation from the mechanical pump to the diverter valve to maintain the 80° C. temperature and then heating blankets set at about 120° C. from the diverter valve to the muffler/trap to prevent condensation of solids prior to entering the muffler/trap. This advantageously avoids the necessity of having to clean out these pipes except maybe after a year or more. Disadvantageously, conventional systems do not have this insulation and heating blankets with the result that the tubing and valving, except for possibly the first foot or so downstream of the mechanical pump, have to be cleaned out every time the filter material is changed which can be about every few months.

In one embodiment, the inlet exhaust line 120 is provided with insulation to maintain a temperature of about 80° C. Temperature sensors or the like interfaced with the automated electronically control system may be utilized, as needed or desired.

In one embodiment, the heating blankets or the like are provided at the exhaust run line 138 to maintain 120° C. temperature control between the diverter valve 122 and the combined trap and muffler 126. Suitable heaters or heating systems and temperature sensors or the like interfaced with the automated electronically control system may be utilized, as needed or desired.

The components of the exhaust conditioning system 110 of embodiments of the invention can comprise various suitable materials such as metals, alloys, ceramics, plastics, among others. In one embodiment, the preferred material is stainless steel.

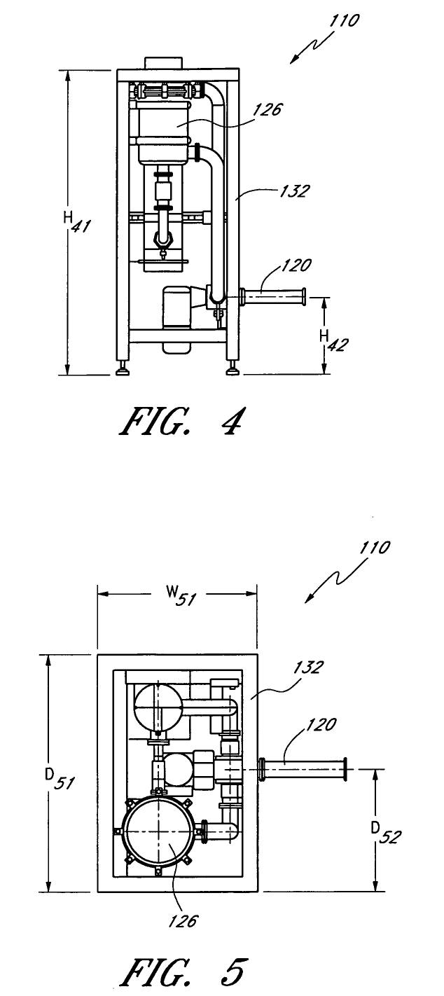

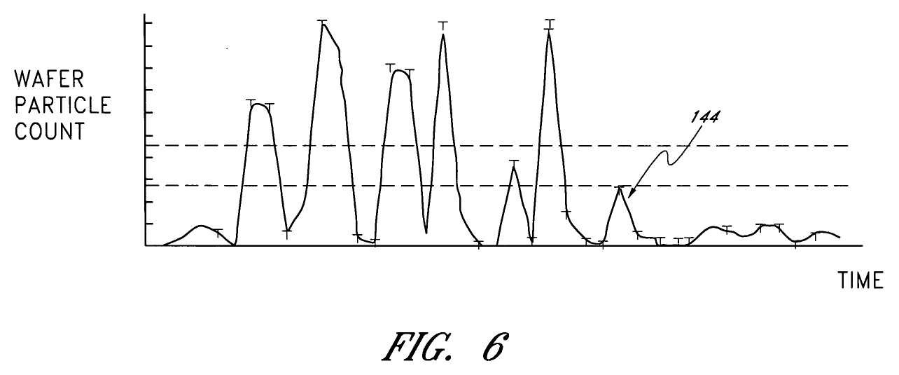

Referring in particular to FIGS. 4 and 5, in one embodiment, the height H₄₁ is about 50.7 inches, the height H₄₂ is about 12.75 inches, the width W₅₁ is about 20 inches, the depth or length D₅₁ is about 30 inches, and the depth or length D₅₂ is about 15.53 inches. In modified embodiments, other suitable dimensions may be efficaciously utilized, as needed or desired.

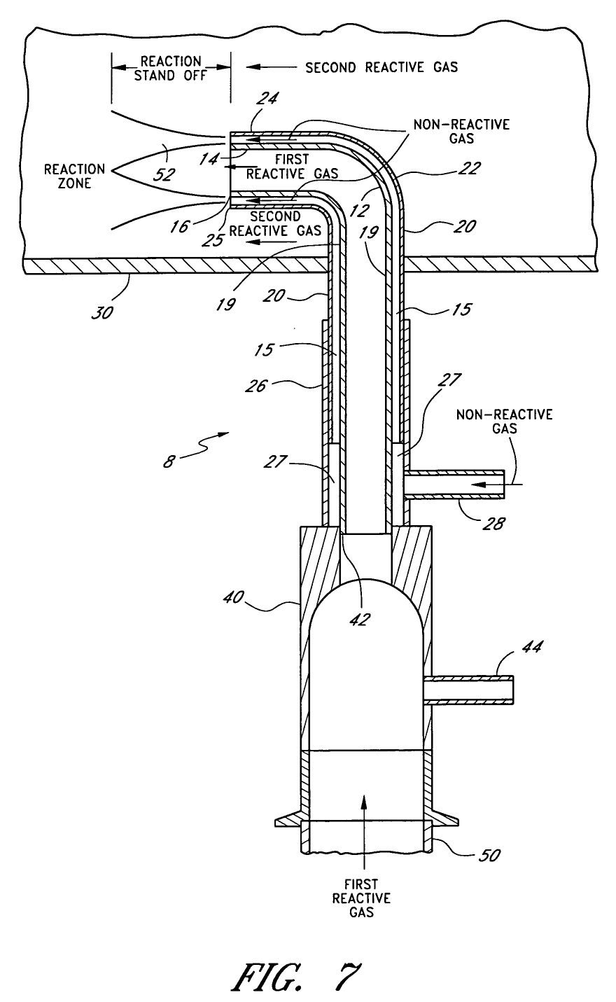

FIG. 6 is a graph showing experimental data that depicts improved semiconductor conductor etch tool performance when utilizing an embodiment of the exhaust conditioning system 110. The exhaust conditioning system 110 was installed on a conductor etch tool at about point 144 and shows a dramatic reduction in the wafer particle or added particles.

Duct Injector Device

U.S. Pat. No. 6,432,372 B2 to Schumacher, the entirety of which is hereby incorporated by reference herein, discloses annular duct injector devices for preventing reactive vapor backstreaming and backstreaming induced deposition, including certain embodiments of the injector device 8 of the exhaust conditioning system 110. Using a single annulus duct injector, exhaust gases containing incompletely reacted moisture sensitive vapors and reaction byproduct moisture sensitive vapors, coming from a semiconductor device fabrication process, are injected into a facility or outlet exhaust line/duct or the like, separated by a “barrier” gas in such a way that clogging of the feed line to the exhaust duct that normally occurs, is prevented. In such applications, downstream momentum is imparted to the reactive gas, and the “diffusion barrier” inert gas, i.e. the injected gases, by other gases (mostly air) flowing in the facility exhaust line.

The function of the barrier gas is twofold. The first function of this gas is to provide a diffusion barrier to reactive gases as they travel downstream, so that reaction between reactive gases occurs only after a differential increment of time during which the diffusion barrier has been overcome, and the reactants have traveled a differential increment of distance downstream from the injection point. This function prevents clogging from occurring at the injection point. The second function of the barrier gas is to prevent turbulence at the periphery of flow at the injection point, and thereby deny entry of reactive species into the “boundary layer” of fluid flowing upstream of the injection point. This second function prevents clogging from occurring upstream of the injection point. Both functions are accomplished by constraining the barrier gas to flow in the laminar flow regime as it approaches from upstream, crosses through, and exits the injection point, in the downstream direction.

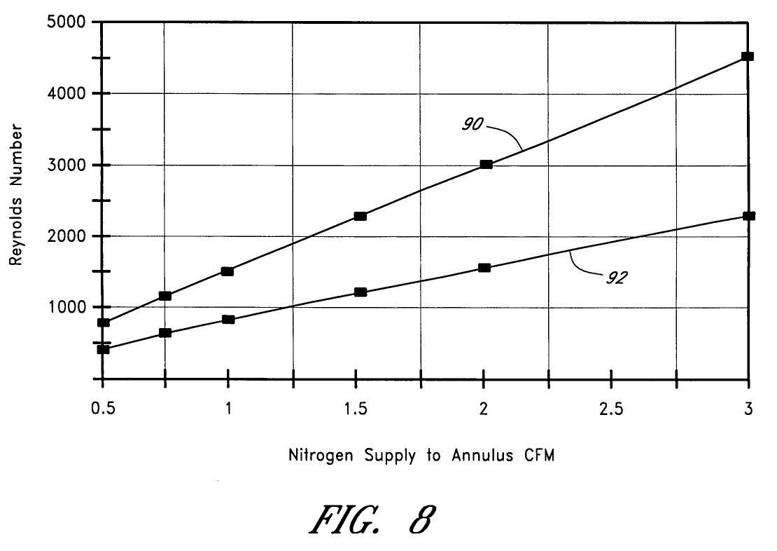

Referring in particular to FIG. 7, the device 8 generally includes a pair of coaxial tubes 19 and 20 which project into the outlet exhaust duct or drop 30. The inner coaxial tube 19 is positioned within the outer coaxial tube 20. An annulus 15 is formed between the coaxial tubes 19 and 20. The coaxial tubes 10 and 20 have right angle bends 12 and 22, respectively, which direct tube sections 14 and 24, respectively, in a direction that is generally parallel with the center axis of the duct 30.

The inner tube 19 is connected to reduction fitting 40 at socket 42. The outer tube 20 is attached to sleeve 26 which is attached to the reduction fitting 40. Annular space 27 is formed between the sleeve 26 and the inner tube 19. Inlet 28 is attached to the sleeve 26. The reduction fitting 40 has a port 44 which may be attached to a pressure gauge (not shown). The exhaust gas inlet line 50 is attached to the reduction fitting 40.

In one embodiment, the second reactive gas is room air from a fan on the facility scrubber or a facility house gas. The reactive components of this reactive gas typically include water vapor, oxygen, mixtures thereof, and the like. In modified embodiments, the second reactive gas can be any gaseous composition comprising moisture or water that is reactive with components in the first reactive gas (e.g., semiconductor etch process exhaust gas).

In one embodiment, the water vapor is generally present in the second reactive gas at concentrations of about 10% humidity to about 100% humidity, including all values and sub-ranges therebetween. In another embodiment, the water vapor is generally present in the second reactive gas at concentrations of about 30% humidity to about 50% humidity, including all values and sub-ranges therebetween. In yet another embodiment, the water vapor is generally present in the second reactive gas at concentrations of about 1% humidity to about 10% humidity, including all values and sub-ranges therebetween.

The non-reactive or inert barrier gas, in one embodiment, includes nitrogen. In another embodiment, the non-reactive or inert barrier gas includes argon. In modified embodiments, the non-reactive gas can be any gaseous composition that is not reactive with the reactive components or species in either the first reactive gas (process exhaust gas) or the second reactive gas.

Referring in particular to FIG. 7, The temperature of the first reactive gas in the tube 19, the non-reactive gas in the annular space 15 and the second reactive gas in the duct 30 can vary over a wide range. In one embodiment, the temperature is in the range from about 10° C. (Celsius or Centigrade) to about 100° C., including all values and sub-ranges therebetween. In another embodiment, the temperature is in the range from about 20° C. to about 30° C., including all values and sub-ranges therebetween. In yet another embodiment, the temperature is in the range from less than about 10° C. to greater than about 100° C., including all values and sub-ranges therebetween.

Still referring in particular to FIG. 7, the pressure of the first reactive gas in the tube 19, the non-reactive gas in the annular space 15 and the second reactive gas in the duct 30 can vary over a wide range. In one embodiment, the pressure is in the range from about minus 10 inches of water to about atmospheric, including all values and sub-ranges therebetween. In another embodiment, the pressure is in the range from about minus 2 inches of water to about atmospheric, including all values and sub-ranges therebetween. In yet another embodiment, the pressure is in the range from less than about minus 10 inches of water to greater than about atmospheric, including all values and sub-ranges therebetween.

In preferred embodiments, the flow of the non-reactive barrier gas through the annular space 15 is laminar or substantially laminar. In one embodiment, the Reynolds Number for the flow of the non-reactive gas through the annular space 15 is generally about 3000 or less, including all values and sub-ranges therebetween. In another embodiment, the Reynolds Number for the flow of the non-reactive gas through the annular space 15 is in the range from about 500 to about 3000, including all values and sub-ranges therebetween. In yet another embodiment, the Reynolds Number for the flow of the non-reactive gas through the annular space 15 is in the range from about 750 to about 2500, including all values and sub-ranges therebetween. In a further embodiment, the Reynolds Number for the flow of the non-reactive gas through the annular space 15 is in the range from about 1000 to about 2000, including all values and sub-ranges therebetween.

The Reynolds Number (Re) for flow of the non-reactive barrier or blanket gas through the annular space 15 is given by:

$$Re = \frac{ρ V ( {D}_{i} - {D}_{o} )}{μ}$$

Where, ρ is the density of the non-reactive gas, V is the velocity of the non-reactive gas, Dᵢ is the inner diameter of the outer tube 20 and Dₒ is the outer diameter of the inner tube 10 and μ is the density of the non-reactive gas. The velocity V can also be represented as:

$$V = \frac{Q}{A}$$

Where, Q is the flow rate of the non-reactive gas and A is the cross-sectional area of the annular space 15.

Thus, for a given non-reactive gas, at a certain temperature and pressure, and fixed geometrical dimensions of the inner and outer tubes 19, 20, the flow rate can be selected to maintain a Reynolds Number such that the flow is laminar or substantially laminar. Alternatively, or in addition, one or both of the flow rate and geometrical dimensions of the inner and outer tubes 19, 20 may be varied to provide a laminar or substantially laminar flow of the non-reactive, inert barrier or blanket gas (in one embodiment, nitrogen).

FIG. 8 is a graph showing the estimated Reynolds Number as a function of the flow rate in cubic feet per minute (CFM) of nitrogen (non-reactive) gas flowing through the annular space 15. The graph illustrates that the Reynolds Number increases with increasing flow rate. Line 90 shows results for an inner tube 19 with a 0.5 inches outer diameter and an outer tube 20 with a 0.75 inches outer diameter and a wall thickness of 0.065 inches. Line 92 shows results for an inner tube 19 with a 1.0 inch outer diameter and an outer tube 20 with a 1.25 inches outer diameter and a wall thickness of 0.065 inches. The density and viscosity of nitrogen are respectively estimated to be 0.07807 lb/ft^{3 and} 178.1 micropoise.

The non-reactive barrier gas provides a plurality of desirable functions. One function of the non-reactive gas is to provide a diffusion barrier to reactive gases as they travel downstream, so that reaction between reactive gases occurs only after a differential increment of time during which the diffusion barrier has been overcome, and the reactants have traveled a differential increment of distance downstream from the injection point. Another function of the barrier gas is to prevent turbulence at the periphery of flow at the injection point, and thereby deny entry of reactive species into the “boundary layer” of fluid flowing upstream of the injection point. Both functions are accomplished by constraining the barrier gas to flow in the laminar flow regime as it approaches from upstream, crosses through, and exits the injection point, in the downstream direction. Advantageously, undesirable backstreaming of moisture, to form exhaust line clogging deposits, is substantially eliminated or reduced.

In embodiments of the invention, the diameters of the inner and outer tubes 19 and 20 can have a wide range of values depending on the specific application. In one embodiment, these diameters are in the range from about 0.5 inches to about 1.5 inches, including all values and sub-ranges therebetween. In another embodiment, these diameters are in the range from about 0.25 inches to about 2 inches, including all values and sub-ranges therebetween. In yet another embodiment, these diameters are in the range from about 0.1 inches to about 10 inches, including all values and sub-ranges therebetween. In modified embodiments, higher or lower diameters may be used, as needed or desired.

In one embodiment, the velocity Vₙ of the non-reactive gas through the annular space 15 is in the range from about 20 ft/sec to about 40 ft/sec, including all values and sub-ranges therebetween. In another embodiment, the velocity Vₙ of the non-reactive gas through the annular space 15 is in the range from about 10 ft/sec to about 60 ft/sec, including all values and sub-ranges therebetween. In yet another embodiment, the velocity Vₙ of the non-reactive gas through the annular space 15 is in the range from about 5 ft/sec to about 100 ft/sec, including all values and sub-ranges therebetween. In modified embodiments, higher or lower velocities Vₙ may be used, as needed or desired.

In one embodiment, the ratio of velocity Vₙ of the non-reactive gas through annular space 15 to the velocity V₁ of the first reactive gas through tube 19 (that is, Vₙ/V₁) is in the range from about 1:2 to about 2:1, including all values and sub-ranges therebetween. In another embodiment, the ratio of velocity Vₙ of the non-reactive gas through annular space 15 to the velocity V₁ of the first reactive gas through tube 19 (that is, Vₙ/V₁) is in the range from about 1:3 to about 3:1, including all values and sub-ranges therebetween. In yet another embodiment, the ratio of velocity Vₙ of the non-reactive gas through annular space 15 to the velocity V₁ of the first reactive gas through tube 19 (that is, Vₙ/V₁) is in the range from about 1:5 to about 5:1, including all values and sub-ranges therebetween. In modified embodiments, other suitable velocity ratios may be used, as needed or desired.

In one embodiment, the ratio of velocity Vₙ of the non-reactive gas through annular space 15 to the velocity V₂ of the second reactive gas through tube 20 (that is, Vₙ/V₂) is in the range from about 1:2 to about 2:1 including all values and sub-ranges therebetween. In another embodiment, the ratio of velocity Vₙ of the non-reactive gas through annular space 15 to the velocity V₂ of the second reactive gas through tube 20 (that is, Vₙ/V₂) is in the range from about 1:3 to about 3:1, including all values and sub-ranges therebetween. In yet another embodiment, the ratio of velocity Vₙ of the non-reactive gas through annular space 15 to the velocity V₂ of the second reactive gas through tube 20 (that is, Vₙ/V₂) is in the range from about 1:5 to about 5:1, including all values and sub-ranges therebetween. In modified embodiments, other suitable velocity ratios may be used, as needed or desired.

Referring in particular to FIG. 7, in operation, the first reactive gas (e.g., a vacuum pump exhaust from a semiconductor reactor system or fabrication process) containing effluent material passes through the inlet line 50 into and through the reduction fitting 40, through the inner tube 19 and into the duct or drop 30. The non-reactive or diffusion barrier gas (e.g., nitrogen, argon, and the like) passes through the inlet 28 into and through the annular space 27, through the annular space 15 and into the duct 30. In one embodiment, the non-reactive gas is advanced to the inlet 28 from a facility source, pressurized tank or cylinder. The flow rate of the non-reactive gas is controlled and/or selected such that its flow is substantially laminar as it flows through the annular space 15 and into the duct 30.

Still referring in particular to FIG. 7, a second reactive gas (e.g., room air from a fan on the facility scrubber or a facility house gas) flows through the duct 30. In one embodiment, a suction fan, which creates a water negative pressure of about 2 to about 5 inches, is used to effect the flow of the gases through the duct 30. The first reactive gas emerges from the inner tube 19 into duct 30 and the non-reactive gas emerges from the annular space 15 into duct 30, both gases flowing in the generally same direction as the second reactive gas.

Still referring in particular to FIG. 7, as the non-reactive gas and the first reactive gas are advanced into the duct 30, the non-reactive gas forms a generally laminar protective layer 52 around the first reactive gas insulating it from the second reactive gas. This generally laminar protective layer prevents convective intermixing and diffusion between the first and second reactive gases. Mixing of the first and second reactive gases does not occur until the first and second reactive gases have traveled downstream to overcome the diffusion barrier 52. As such, a reaction stand off zone is created between the ends 16 and 25 of coaxial tubes 19 and 20, respectively, and the point downstream from ends 16 and 25 where the first and second reactive gases come into contact.

Still referring in particular to FIG. 7, the point downstream where the first and second reactive gases contact each other is the beginning of the reaction zone where the first and second reactive gases react with each other. The reaction stand off zone, as well as upstream locations within tube 19 and annular space 15, are harmful locations wherein reaction between the first and second reactive gases are to be avoided. The reaction zone downstream from the reaction stand off zone is a non-harmful location wherein reaction between the first and second reactive gases are permitted. Thus, water vapor from the second reactive gas is prevented from backstreaming—into the process exhaust—through the device 8, the piping 50 to the exhaust lines and possibly to the vacuum pump 112 thereby preventing solid particulate deposition, in the exhaust line(s) and possibly the pump 112, formed by reaction between the moisture and exhaust.

Convective intermixing of the active species in the first and second reactive gas streams, that is fluorine and water vapor respectively, at the end 16 of tube 19 is prevented by the non-reactive gaseous layer 52. Because of the presence of substantially laminar gaseous layer 52, mixing of the first and second reactive gases is delayed by the diffusion barrier 52. Eddy currents backstreaming into the tube 19 are eliminated or substantially eliminated, and diffusional intermixing does not occur until some distance downstream of the end 16 of the tube 19 (i.e., in the reaction zone) of outlet duct or drop 30. Thus, active species, that is moisture in this case, do not enter the tube 19 and reach the exhaust lines, and possibly the pump 112, thereby advantageously preventing or substantially reducing deleterious backstreaming induced clogging and desirably providing beneficial process control and performance to the semiconductor fabrication process.

One example of a chemical reaction path that can lead to undesirable clogging in the exhaust line is when boron trichloride in the exhaust reacts with backstreaming moisture to form boric acid or boron oxide according to:
BCl₃+3H₂O→H₃BO₃+3HCl
2BCl₃+6H₂O→B₂O3+6HCl
The gas injector device 8 of embodiments of the invention prevents undesirable moisture backstreaming, and therefore clogging of the vacuum exhaust from this source

The components of the injector device of embodiments of the invention may comprise various suitable materials such as metals, alloys, ceramics, plastics, among others. In one embodiment, the preferred material is stainless steel, for example, 3161 stainless steel. A suitable finish may be provided or applied, as needed or desired.

Some embodiments provide an improved scrubbed exhaust flow pattern by utilizing the gas injector device 8 of embodiments of the invention. The injector device 8 introduces process effluent into the core of the main flow in the scrubbed exhaust, bypassing the boundary layer that exists at the periphery of flow. From this injection point the effluent flow diverges in a cone shaped fashion downstream until it reaches the boundary layer. During this divergence the process effluent reacts with moisture present in the scrubbed exhaust to form submicron particles of oxides of the water reactive compounds in the effluent, so that what appears to be a cone of cigarette smoke is formed. Flow in the main core is turbulent keeping this particulate matter suspended as it flows downstream towards the facility water scrubber that will remove it from the gas stream exiting the facility. Only small quantities of this particulate matter are trapped in the boundary layer causing a thin coating of metal oxide to be formed on the walls of the scrubbed exhaust duct, that is uniform around its circumference. Thus the majority of the oxides formed when introducing moisture reactive process effluent into the scrubbed exhaust, reach the facility scrubber and are captured there.

When the injector device 8 is not used however, moisture sensitive process effluent is on the other hand introduced directly into the slowly moving boundary layer at the periphery of flow, reacts there and tends to agglomerate on the bottom of the scrubbed exhaust duct. While some of the moisture sensitive material may be removed by a point of use scrubber prior to entering the scrubbed exhaust, such devices are neither 100% effective or actively working (not in Bypass) 100% of the time.

Thus, advantageously, the gas injector device 8 improves delivery of oxides formed by moisture in the scrubbed exhaust to the facility scrubber, and desirably reduces deposition of these oxides in the exhaust ductwork.

Combined Muffler and Trap

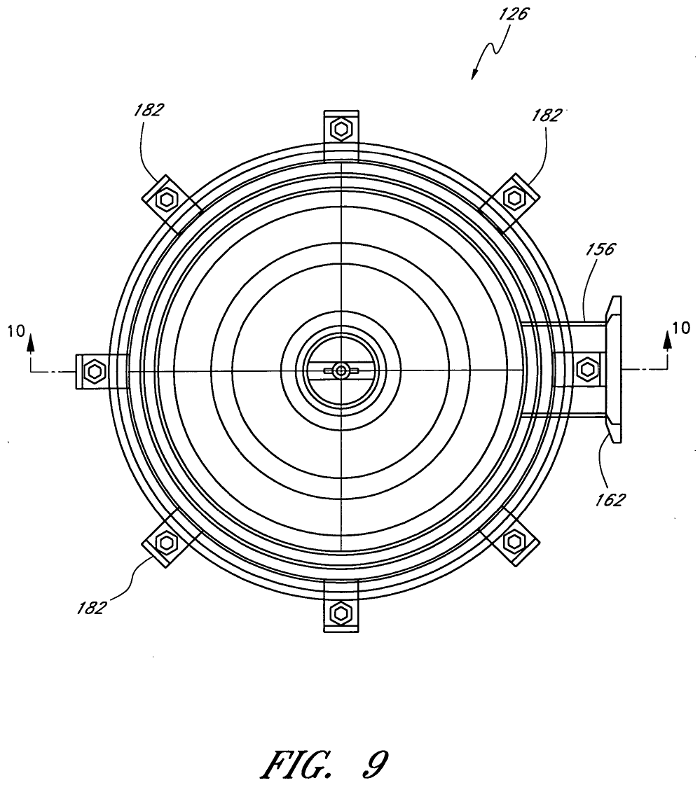

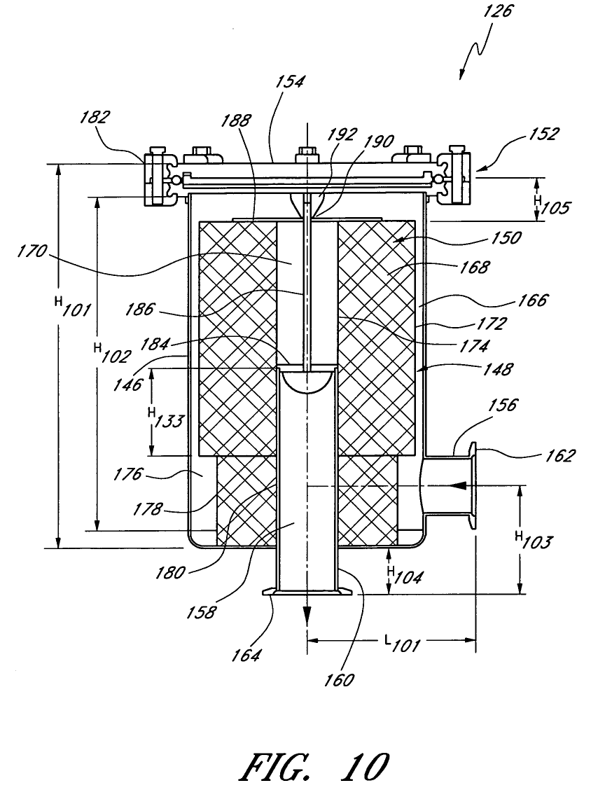

FIGS. 9 and 10 show different views of one embodiment of the combined muffler and trap 126. The combined trap and muffler 126 is specially designed in accordance with embodiments of the invention to perform the dual roles of removing particulates and/or condensable vapor from the process exhaust and muffling pump associated noise or sound. It should be noted that as-is commercially available traps in fact act as base amplifiers not mufflers when placed on a mechanical vacuum pump exhaust from which the standard muffler has been removed.

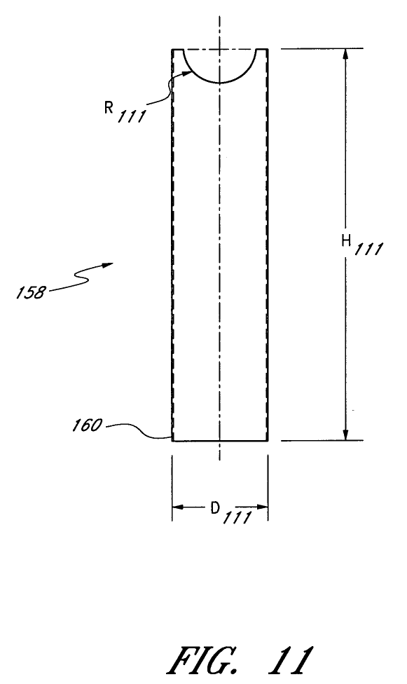

The combined trap and muffler 126 generally comprises a generally cylindrical main outer body portion 146, a generally cylindrical inner chamber 148 housing a filter system 150, a clamping mechanism or system 152 that sealingly secures a removable or liftable top lid or assembly 154, an exhaust inlet 156 and a tube 158 (also shown in FIG. 11) that has an exhaust outlet 160 at one end. In one embodiment, the outer body 146 has an outer diameter of about 8 inches and a wall thickness of about 0.083 inches.

The inlet 156 is connected to the first exhaust run line 138 and allows process exhaust or effluent to flow into the trap/muffler inner chamber 148. One or more flanges 162 or the like are provided at the inlet 156 to facilitate connection to the first exhaust run line 138. In one embodiment, the inlet 156 has an outer diameter of 2 inches and a wall thickness of about 0.065 inches.

The outlet or exit 158 is connected to the second exhaust run line 140 and allows process exhaust or effluent to flow from the trap/muffler inner chamber 148 to the injector device 8. One or more flanges 164 or the like are provided at the outlet 158 to facilitate connection to the second exhaust run line 140. In one embodiment, the outlet 158 has an outer diameter of 2 inches and a wall thickness of about 0.065 inches.

In the illustrated embodiment, the chamber 148 comprises an upper first chamber 166 that houses a generally annular first filter or filter element 168 of the filter system 150. The filter 168, in one embodiment, comprises a gauze or wire mesh. In one embodiment, the gauze comprises stainless steel with an outer diameter of about 7.5 inches and a height of about 8 inches.

The filter 168 comprises a generally central passage 170. In one embodiment, the filter 168 is provided with an outer wrap gauze (with wire screen) 172 and an inner gauze barrier (perforated tube) 174.

In the illustrated embodiment, the chamber 148 comprises a lower second chamber 176 that houses a generally annular second filter or filter element 178 of the filter system 150. The filter 178, in one embodiment, comprises a gauze or wire mesh. In one embodiment, the gauze comprises stainless steel with an outer diameter of about 6 inches.

The filter 178 comprises a generally central passage 180. In one embodiment, the filter 178 is provided with an outer wrap gauze (with wire screen).

The utilization of the second filter 178 is advantageous in muffling vacuum pump exhaust noise or sound. Other factors that may be beneficial in muffling undesirable noise or sound include the configuration and arrangement of the components within the inner chamber 148 of the trap/muffler 126. Advantageously, enhanced sound or noise absorption and cancellation is achieved by the combined trap and muffler to provide a substantially quiet exhaust conditioning system.

In one embodiment, the first filter 168 and the second filter 178 comprise discrete or independent units that are in fluid communication with one another. In another embodiment, the first filter 168 and the second filter 178 comprise an integral unit.

The tube 158 has an upstream portion or end that extends into the passage 170 of the first filter 168. The tube 158 extends through the passage 180 of the second filter 178 and beyond at the downstream tube end 160. Referring in particular to FIG. 11, the diameter D₁₁₁ is about 2 inches, the height H₁₁₁ is about 7.5 inches and the radius of curvature R₁₁₁ is about 0.75 inches.

The clamping system 152 is used to engage the top lid or plate 154 so as to seal the inner chamber 148 through which the exhaust or effluent flows. In one embodiment, the clamping system 152 comprises a plurality of clamping or locking elements 182. The clamping elements 182 can engage a ring flange or the like and a flange or the like of the top lid 154 to provide appropriate sealing using a seal element or the like.

In one embodiment, the clamping system sealing element comprises an O-ring. In another embodiment, the clamping system sealing element comprises a KF type seal or fitting that is advantageous at higher temperatures. For example, a “Hot Gas Sweep” (HGS) may be performed to sweep particles out of the process tool to further improve yield, as needed or desired.

The clamping system 152 is operable to temporarily remove or lift the sealing plate 154 and gain access to the interior of the combined trap and muffler 126. This allows one or both of the filters 168, 178 to be cleaned, washed, serviced and/or replaced, as needed or desired. In embodiments of the invention, the pump back pressure is used to determine when to switch to bypass mode and attend to the filters 168, 178.

In the illustrated embodiment, the combined trap and muffler 126 comprises a bar 184, a threaded rod 186, a plate 188, a washer 190 and a wing nut 192 within the interior chamber 148 to facilitate in keeping the filters 168, 178 in place. The bar 184 is seated on the top of the tube 158.

The rod 186 extends through the space 170 and is engaged with the bar 184 and the plate 188. In one embodiment, the rod 186 comprises a ¼-20 threaded rod.

The plate 188 is seated on the top of the first filter 168. In one embodiment, the plate 188 has an outer diameter of about 5 inches and a thickness of about 0.065 inches.

The washer 190 is seated on the plate 188 and the rod 186 passes through the washer 190. In one embodiment, the washer 190 comprises ¼ inch lock washer.

The wing nut 192 is seated on the washer 190 and is threadably engaged with the rod 186. When needed, the nut 192 may be removed to gain access to the filters 168, 178 for servicing and/or replacement. In one embodiment, the nut 192 comprises a ¼-20 wing nut.

The process exhaust or effluent flows into the combined trap and muffler 126 through the inlet 156 and then flows through the filters 178 and 168. The exhaust then flow through the perforated tube 174 and into the passage 170 and tube 158 and exits the combined trap and muffler 126 through the outlet 160. The filters 178 and 168 trap exhaust particulates and/or condensable vapor and are serviced or replaced when the back pressure rises by a predetermined value or reaches a predetermined threshold value. The special configuration and/or arrangement of the combined trap and muffler 126 and/or the filter system 150 desirably also muffles pump exhaust noise or sound.

In some embodiments, no muffler is provided at the vacuum pump 112, in the vacuum pump 112 and between the vacuum pump 112 and the diverter valve 122. The combined trap and muffler 126 of embodiments of the invention replaces this conventional pump muffler. Advantageously, the combined trap and muffler 126 is easily accessible, easy to maintain and economic in cost.

The combined trap and muffler 126 may be mounted in any suitable orientation in the exhaust conditioning system 110. That is, when mounted, the lid 154 does not necessarily have to be on the top.

The combined trap and muffler 126, in some embodiments, is desirably configured to hold a volume of filter material that would allow operation for a predetermined time period. In one embodiment, this time period is at least four (4) months. In other embodiments, the combined trap and muffler 126 may be configured to allow operation for other suitable time periods with efficacy, as needed or desired.

The combined trap and muffler may be fabricated by any one of a number of suitable vendors. For example, one suitable vendor includes Nor-Cal Products, Inc. of Yreka, Calif.

The components of the combined trap and muffler of embodiments of the invention may comprise various suitable materials such as metals, alloys, ceramics, plastics, among others. In one embodiment, the preferred material is stainless steel, for example, 3161 or 304 stainless steel. A suitable finish may be provided or applied, as needed or desired.

Referring in particular to FIG. 10, in one embodiment, the height H₁₀₁ is about 13.1 inches, the height H₁₀₁ is about 13.1 inches, the height H₁₀₂ is about 11.5 inches, the height H₁₀₃ is about 3.6 inches, the height H₁₀₄ is about 1.5 inches, the height H₁₀₅ is about 1.5 inches, and the length or width L₁₀₁ is about 5.7 inches. In modified embodiments, other suitable dimensions may be efficaciously utilized, as needed or desired.

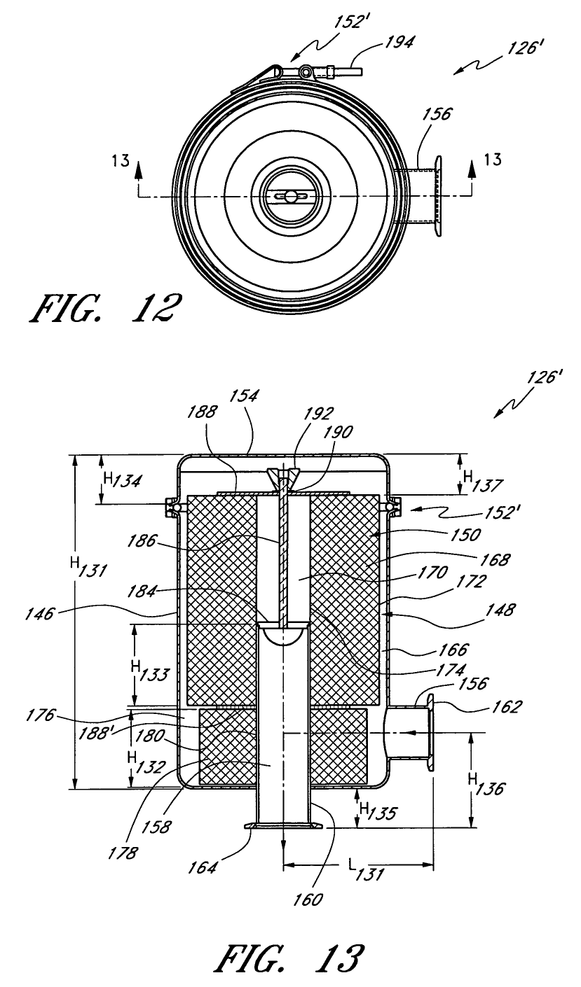

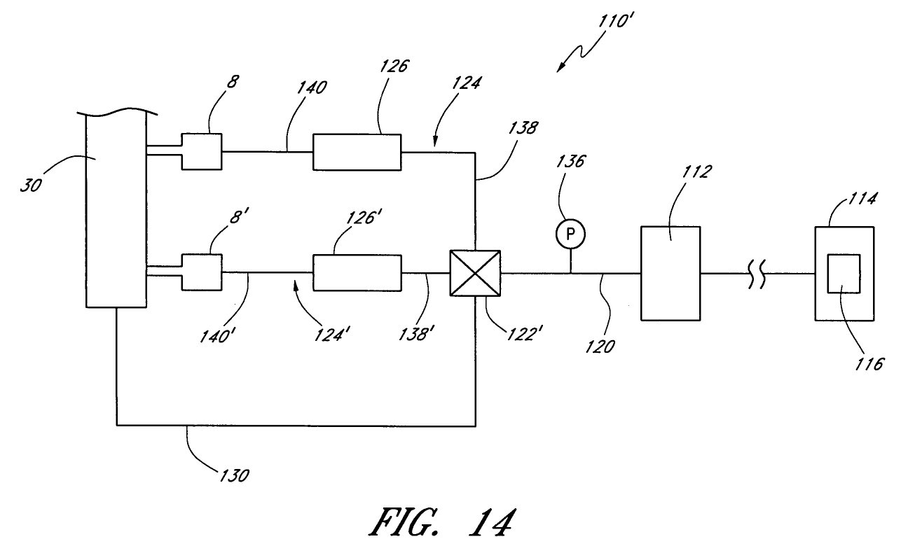

FIGS. 12 and 13 show different views of a combined muffler and trap 126′ in accordance with a modified embodiment. As can be seen from the drawings, the combined muffler and trap 126 is generally similar to the combined muffler and trap 126 (FIGS. 9 and 10) except for a few features.

The combined muffler and trap 126′ comprises a different clamping or locking mechanism or system 152′ that sealingly secures the removable or liftable top lid 154. The clamping mechanism 152′ is provide with a clamp and O-ring to engage respective flanges of the lid 154 and the main body 146 to seal the inner chamber 148. A lever or latch mechanism 194 may be operated to clamp and unclamp the lid 154, as and when needed.

A lower annular plate 188′ (FIG. 13) may or may not be provided between the first and second filter elements 168 and 178. In one embodiment, the plate 188′ is provided to support the first filter element 168 and the second filter element 178 is not provided in the lower inner chamber portion 176. This embodiment without filter material in the lower chamber portion 176 is generally noisy and not that effective in muffling noise or sound.

Referring in particular to FIG. 13, in one embodiment, the height H₁₀₁ is about 13.1 inches, the height H₁₃₁ is about 12.8 inches, the height H₁₃₂ is about 3.0 inches, the height H₁₃₃ is about 3.0 inches, the height H₁₃₄ is about 2.0 inches, the height H₁₃₅ is about 1.5 inches, the height H₁₃₆ is about 3.6 inches, the height H₁₃₇ is about 1.5 inches, and the length or width L₁₃₁ is about 5.7 inches. In modified embodiments, other suitable dimensions may be efficaciously utilized, as needed or desired.

System Operation

When the process exhaust passes through the exhaust run line 140, it flows through the combined trap and muffler 126 and the gas injector 8 and into the duct 30. The pressure gauge, sensor or transducer 136 monitors the back pressure at or proximate the vacuum pump exit. The diverter valve 122 is actuated or operated to direct the exhaust through the exhaust bypass line 130 if the back pressure (as measured by the pressure gauge, sensor or transducer 136) increases by a predetermined pressure differential (ΔP) or exceeds a threshold pressure value. Advantageously, this allow substantially continuous operation of the semiconductor processing chamber 116 without undesirable interruption.

In one embodiment, the predetermined pressure differential (ΔP) is in the range from about 0.1 psi to about 0.5 psi. In another embodiment, the predetermined pressure differential (ΔP) is in the range from about 0.2 psi to about 0.4 psi. In yet another embodiment, the predetermined pressure differential (ΔP) is about 0.3 psi. In modified embodiments, other suitable pressure differentials may be utilized with efficacy, as needed or desired.

In one embodiment, the predetermined pressure differential (ΔP) is based on a nominal back pressure of about 3 psi. That is, if the back pressure rises to (3+ΔP) psi, the flow is switched to the bypass mode. In another embodiment, the predetermined pressure differential (ΔP) is based on a nominal back pressure of about 3 psi to about 8 psi.

When the exhaust is diverted to the bypass exhaust bypass line 130, an operator or technician can tend to the combined muffler and trap 126. Once the combined muffler and trap 126 has been attended to, the diverter valve 122 is actuated to redirect the exhaust flow through the exhaust run line.

In one embodiment, one or both of the filter elements 168, 178 are washed, cleaned and/or serviced and then reused. In another embodiment, one or both of the filter elements 168, 178 are replaced by new filter material or media. In yet another embodiment, the combined trap and muffler 126 is replaced by a new combined trap and muffler. Advantageously, washing, cleaning, servicing and/or replacement steps are quick and simple

The combined trap and muffler 126, in some embodiments, is desirably configured to hold a volume of filter material that would allow operation for a predetermined time period. In one embodiment, this time period is at least four (4) months. In other embodiments, the combined trap and muffler 126 may be configured to allow operation for other suitable time periods with efficacy, as needed or desired.

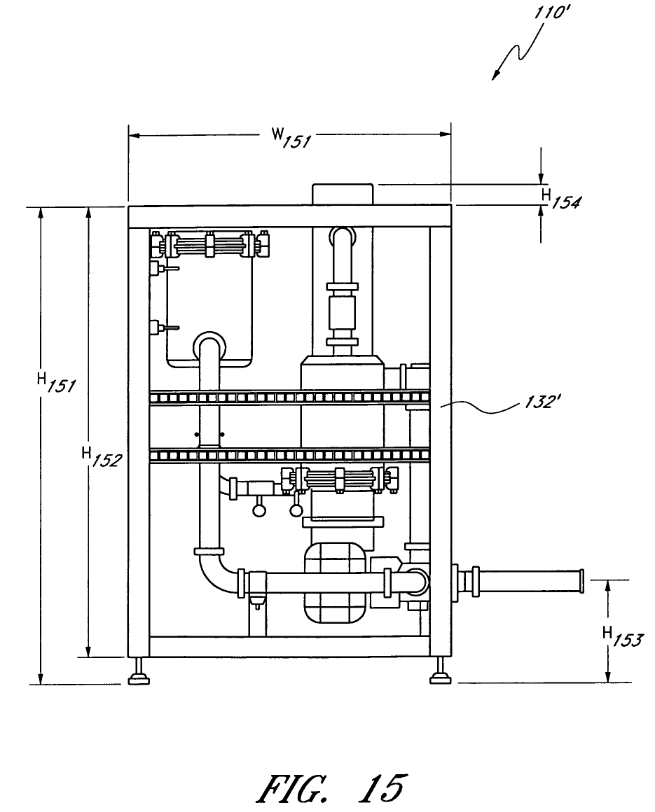

In one embodiment, an additional or second exhaust run line is provided with a second combined trap and muffler and a second injector device, as discussed further below in connection with FIGS. 14 and 15. In this case, the diverter valve 122 can be actuated or operated to direct the exhaust through the second exhaust run line if the back pressure (as measured by the pressure gauge, sensor or transducer 136) increases by a predetermined pressure differential (ΔP) or exceeds a threshold pressure value. Then the operator or technician has more time to tending to the first combined trap and muffler 126. When the back pressure again increases by a predetermined pressure differential (ΔP) or exceeds a threshold pressure value, the diverter valve 122 is again actuated to redirect the exhaust through the first combined trap and muffler 126. This switching between the two traps is repeated as the exhaust conditioning system operates. The exhaust bypass line 130 may also be utilized, as needed or desired

Embodiments of the exhaust conditioning system electronics package provides several beneficial features and advantages. These include (a) allowing operator switching to bypass at any time, (b) actuating the diverter valve to direct flow to the second filter unit (second combined muffler and trap) or to bypass when backpressure increases by ΔP, (c) switching flow to bypass on receipt of a signal from Hot Gas Sweep (HGS) equipment, and (d) allowing remote monitoring and control via an RS 232 port or the like.

The methods which are described and illustrated herein are not limited to the sequence of acts described, nor are they necessarily limited to the practice of all of the acts set forth. Other sequences of acts, or less than all of the acts, or simultaneous occurrence of the acts, may be utilized in practicing embodiments of the invention.

Some Other Embodiments

FIGS. 14 and 15 show another embodiment of an exhaust or effluent conditioning or treatment system 110′ with a frame 132′. The exhaust conditioning system 110′ comprises an additional exhaust run line 140′, including a first exhaust run line 138′ and a second exhaust run line 140′, a second combined trap and muffler 126′ and a second gas injector device 8′. Selected portions of the exhaust run line 140′ can be insulated and/or heated, as discussed above.

The diverter valve 122′ can comprise a three-way valve, equivalent or the like that allows for switching exhaust flow path between the run lines 138, 138′ and the bypass line 130 based on back pressure measurements by the pressure gauge, sensor or transducer 136. In one embodiment, the diverter valve 122′ comprises a pneumatic or pneumatically actuated valve.

The automated and electronically supported exhaust conditioning system 110′, in one embodiment, has a weight of about 300 lbs, a compact frame (or substantially overall) size of about 32 inches (width)×30 inches (depth or length)×50 inches (height), utilizes utility nitrogen (about 10 psig pressure) at a flow rate of about 1 CFM as the barrier gas for the injector devices 8 and 8′, utilizes compressed air at a pressure of about 80 psig to operate the pneumatically actuated diverter valve 122′, and utilizes 110 volt AC and 5 amp electrical power connections.

Referring in particular to FIG. 15, in one embodiment, the height H₁₅₁ is about 48 inches, the height H₁₅₂ is about 45.33 inches, the height H₁₅₃ is about 10.00 inches, the height H₁₅₄ is about 2.0 inches, and the width W₁₅₁ is about 32.00 inches. In modified embodiments, other suitable dimensions may be efficaciously utilized, as needed or desired.

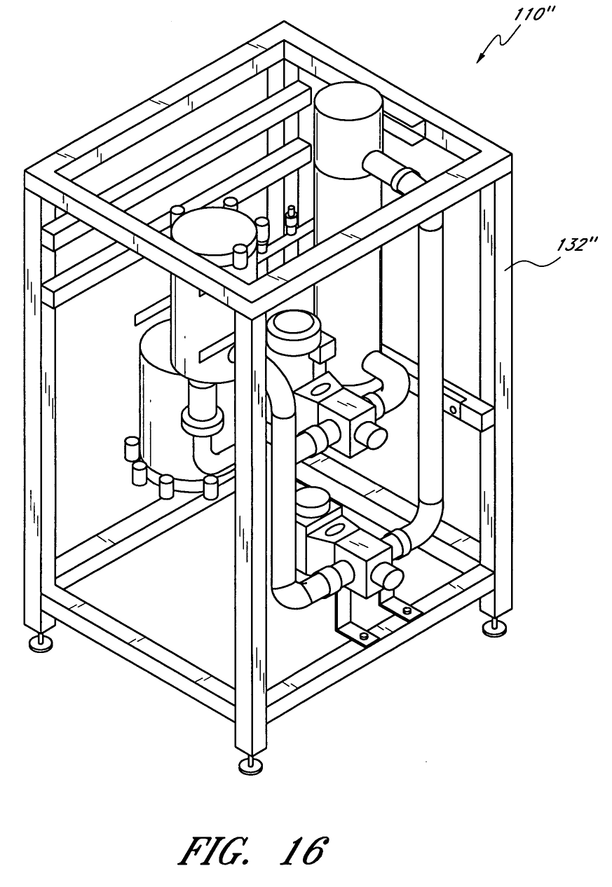

FIG. 16 shows another embodiment of an exhaust or effluent conditioning or treatment system 110″. The automated and electronically supported exhaust conditioning system 110″ comprises two exhaust conditioning systems 110 housed in a compact single frame 132″. These two systems 110 can operate independently of one another.

The automated and electronically supported exhaust conditioning system 110″, in one embodiment, has a weight of about 400 lbs, a compact frame (or substantially overall) size of about 28 inches (width)×30 inches (depth or length)×55 inches (height), utilizes utility nitrogen (about 10 psig pressure) at a flow rate of about 2 CFM as the barrier gas for the two injector devices 8, utilizes compressed air at a pressure of about 80 psig to operate the two pneumatically actuated diverter valves 122, and utilizes 110 volt AC and 5 amp electrical power connections.

Some Features and Benefits

Some embodiments of the exhaust conditioning system provide the following beneficial features:
1. Simple design with rugged stainless steel construction and no moving parts.
2. Uses laminar flow N₂ blanket and solids filter to eliminate wall deposits and backstreaming of O₂ and H₂O.
3. Teflon coated where exposed to corrosive environment in scrubbed exhaust.
4. Easy to install between mechanical pump and scrubbed exhaust. Two simple connections.
5. Filter replaces Dry Pump muffler and is quieter.
6. Utilities include compressed air (80 psig) for pneumatic valve actuation and N₂ (10 psig) feed to unit. Two plug and play 110vac 5A electrical connections.
7. Parallel Run/Bypass design facilitates filter element replacement without process downtime. Backpressure sensor activated switching available.
8. 30,000 (200 mm) wafer filter life achieved while maintaining back pressure build-up to <0.1 psi in high volume (6000 wafers/month) manufacturing.
9. Excellent candidate for Cost Reduction Programs as well as Energy Efficiency and ESH Upgrade Programs. Reduces Environmental Footprint.
10. End of Pipe Technology on “Scrubbed Exhaust” provides required air pollution control and abatement.

Some embodiments of the exhaust conditioning system provide the following advantages and benefits:

One important advantage of some embodiments is a reduction in the conductor etch process overall “cost of ownership” including:
1. Low maintenance, small footprint and high reliability
2. No water or fuel and minimal electricity use. Reduces greenhouse gas emissions
3. Positive cash flow from Project start when compared to all POU options in an analysis of capacity expansion alternatives.
4. 6 to 18 month ROI when replacing POU scrubbers in cost reduction or energy efficiency upgrade Projects.
5. Some public utilities provide energy efficiency incentives for Paragon use that vary from 5% to 50% of CapEx.

Another important advantage of some embodiments is improved process control including:
1. Precise monitoring of pump back pressure in real time.
2. Maintains pumping speed over extended periods of time.
3. Low cost of filter provides an incentive to replace it as soon as backpressure rises. The high cost of POU filters on the other hand provides a disincentive for filter replacement leading to high, uncontrolled backpressure

Yet another important advantage of some embodiments is reduction in yield killing defects added by conductor etch process.

From the foregoing description, it will be appreciated that a novel approach for semiconductor processing exhaust treatment has been disclosed. While the components, techniques and aspects of the invention have been described with a certain degree of particularity, it is manifest that many changes may be made in the specific designs, constructions and methodology herein above described without departing from the spirit and scope of this disclosure.

While a number of preferred embodiments of the invention and variations thereof have been described in detail, other modifications and methods of using and medical applications for the same will be apparent to those of skill in the art. Accordingly, it should be understood that various applications, modifications, and substitutions may be made of equivalents without departing from the spirit of the invention or the scope of the claims.

Various modifications and applications of the invention may occur to those who are skilled in the art, without departing from the true spirit or scope of the invention. It should be understood that the invention is not limited to the embodiments set forth herein for purposes of exemplification, but is to be defined only by a fair reading of the appended claims, including the full range of equivalency to which each element thereof is entitled.

1. An exhaust system for a semiconductor processing chamber, comprising:
a diverter valve downstream of a vacuum pump that is downstream of said semiconductor processing chamber;
a pressure sensor upstream of said diverter valve for monitoring pump back pressure;
an exhaust run line downstream of said diverter valve through which exhaust from said semiconductor processing chamber is fed to a facility exhaust line;
an exhaust bypass line downstream of said diverter valve and arranged in a parallel configuration with said exhaust run line;
a filter at said exhaust run line to capture at least a portion of particulates and/or condensable vapor of said exhaust as it passes through said filter;
whereby, said diverter valve is actuated to direct said exhaust through said exhaust bypass line if said back pressure as measured by said pressure sensor increases by a predetermined pressure differential (ΔP) to allow substantially continuous operation of said semiconductor processing chamber.

2. The system of claim 1, wherein said system further comprises an injector device that feeds in said facility exhaust line and substantially prevents backstreaming induced deposition.

3. The system of claim 2, wherein said injector device comprises an inner passage through which said exhaust flows and an outer passage through which a barrier gas flows in a laminar flow regime.

4. The system of claim 1, wherein said exhaust run line is insulated and/or heated to provide temperature control.

5. The system of claim 1, wherein said system further comprises a second exhaust run line with a second filter.

6. The system of claim 1, wherein said filter serves as a combined particle trap and muffler.

7. The system of claim 1, wherein said filter is replaceable without interruption of the operation of said semiconductor processing chamber.

8. The system of claim 1, wherein said filter comprises a first inner chamber that contains a first filter element.

9. The system of claim 8, wherein said filter comprises a second inner chamber that contains a second filter element and allows said filter to serve as a sound muffler.

10. The system of claim 8, wherein said filter element comprises gauze.

11. The system of claim 10, wherein said gauze comprises stainless steel.

12. The system of claim 1, wherein said system further comprises a controller to monitor and automatically control system operation.

13. The system of claim 1, wherein said system further comprises an alarm that is activated when said back pressure as measured by said pressure sensor increases by said predetermined pressure differential (ΔP).

14. The system of claim 1, wherein said predetermined pressure differential (ΔP) is in the range from about 0.1 psi to about 0.5 psi.

15. The system of claim 14, wherein said predetermined pressure differential (ΔP) is in the range from about 0.2 psi to about 0.4 psi.

16. The system of claim 15, wherein said predetermined pressure differential (ΔP) is about 0.3 psi.

17. The system of claim 1, wherein said diverter valve comprises a pneumatically actuated valve.

18. A method of directing exhaust from a semiconductor processing chamber, comprising:
flowing said exhaust through a diverter valve downstream of a pump that provides sub-atmospheric pressure to said semiconductor processing chamber;
flowing said exhaust through a filter downstream of said valve to remove at least a portion of particulates and/or condensable vapor of said exhaust;
feeding said exhaust that passes through said filter to a facility exhaust line downstream of said filter;
monitoring back pressure intermediate said pump and said valve; and
operating said valve to divert said exhaust to an exhaust bypass line if said back pressure increases by a predetermined pressure differential (ΔP) to allow substantially continuous operation of said semiconductor processing chamber.

19. The method of claim 18, wherein said method further comprises muffling noise from said exhaust after it exits said pump by providing a secondary filter element in said filter.

20. The method of claim 18, wherein said method further comprises operating said valve to divert said exhaust through a second filter.

21. The method of claim 20, wherein said method further comprises replacing a filter element of said filter while said exhaust flows through said second filter.

22. The method of claim 21, wherein said method further comprises operating said valve to redirect said exhaust through said filter with said replaced filter element if said back pressure increases by said predetermined pressure differential (ΔP).

23. The method of claim 20, wherein said method further comprises cleaning said filter while said exhaust flows through said second filter.

24. The method of claim 23, wherein said method further comprises operating said valve to redirect said exhaust through said cleaned filter if said back pressure increases by said predetermined pressure differential (ΔP).

25. The method of claim 18, wherein when said back pressure increases by said predetermined pressure differential (ΔP) an alarm is activated.

26. The method of claim 18, wherein said method further comprises flowing said exhaust through an injector device downstream of said filter that substantially prevents reactive vapor backstreaming.

27. The method of claim 26, wherein said method further comprises flowing an inert gas through said injector device at a Reynolds number that is about 3000 or less.

28. The method of claim 18, wherein said method further comprises replacing said filter while said exhaust flows through said exhaust bypass line.

29. The method of claim 18, wherein said method further comprises replacing at least one filter element of said filter while said exhaust flows through said exhaust bypass line.

30. The method of claim 29, wherein said method further comprises replacing two filter elements of said filter while said exhaust flows through said exhaust bypass line.

31. The method of claim 18, wherein said method further comprises cleaning at least one filter element of said filter while said exhaust flows through said exhaust bypass line.

32. The method of claim 18, wherein said method further comprises operating said valve to redirect said exhaust back through said filter after said filter has been replaced and/or serviced.

33. The method of claim 18, wherein said method further comprises automatically controlling the operation of said valve.

34. The method of claim 18, wherein said method further comprises providing remote monitoring and control of system operation.

35. An exhaust system for a semiconductor processing chamber, comprising:
an exhaust line downstream of a vacuum pump that is downstream of said semiconductor processing chamber;
a trap in said exhaust line comprising a chamber filled with filter material, wherein the trap serves as a muffler of exhaust noise and no other muffler is provided in said vacuum pump and between said vacuum pump and said trap; and
an injector downstream of said trap that feeds into a facility exhaust, said injector configured to prevent reactive vapor backstreaming and backstreaming induced deposition.

36. The system of claim 35, wherein said injector comprises an inner passage through which exhaust flows and an outer passage through which an inert barrier gas flows.

37. The system of claim 36, wherein said barrier gas flows in a laminar flow regime.

38. The system of claim 37, wherein said barrier gas is comprises nitrogen or argon.

39. The system of claim 35, wherein said filter material is replaceable.

40. The system of claim 35, wherein said filter material is serviceable and reusable.

41. The system of claim 35, wherein at least a portion of said filter material serves as muffler of exhaust noise.

42. The system of claim 35, wherein said filter material comprises a first filter portion and a second filter portion.

43. The system of claim 42, wherein said first filter portion and said second filter portion comprise discrete units.

44. The system of claim 42, wherein said first filter portion and said second filter portion comprise an integral unit.

45. The system of claim 35, wherein said chamber of said trap is configured to hold a volume of filter material that would allow operation of said trap for a predetermined time period.

46. The system of claim 45, wherein said time period is at least four months.

47. The system of claim 35, wherein said filter material comprises gauze.

48. The system of claim 47, wherein said gauze comprises stainless steel.
